(19) United States
(12) Patent Application Publication
(10) Pub. No.: US 2025/0365947 A1
(43) Pub. Date: Nov. 27, 2025

(54) POWER PERFORMANCE AREA ATTRACTIVE MULTIPLE TRANSISTOR ANTI-FUSE BIT CELL LAYOUT STRUCTURE

(71) Applicant: Taiwan Semiconductor Manufacturing Company Ltd., Hsinchu (TW)

(72) Inventors: Yuhsiang Chen, Pingtung City (TW); Yao-Jen Yang, Hsinchu (TW); Ji Kuan Lee, Taipei City (TW)

(73) Assignee: Taiwan Semiconductor Manufacturing Company Ltd., Hsinchu (TW)

(21) Appl. No.: 19/292,408

(22) Filed: Aug. 6, 2025

Related U.S. Application Data
(63) Continuation of application No. 18/519,452, filed on Nov. 27, 2023.
(60) Provisional application No. 63/517,784, filed on Aug. 4, 2023.

(51) Int. Cl. H10B 20/25

(52) U.S. Cl. CPC H10B 20/25

(57) ABSTRACT

A memory array includes a continuous active region extending along a direction. The memory array includes a first bit cell, which includes a first programming device and a pair of first reading devices defined on the continuous active region. The memory array includes a first programing word line coupled to a gate of the first programing device. The memory array includes a first reading word line coupled to gates of the pair of first reading devices. The memory array includes a bit line, wherein a first one of the pair of first reading devices is coupled between a first source/drain node of the first programing device and the bit line.

### CROSS-REFERENCES TO RELATED APPLICATIONS

This application is a continuation of and claims priority to U.S. patent application Ser. No. 18/519,452, filed Nov. 27, 2023, which claims the benefit of and priority to U.S. Provisional Patent Application No. 63/517,784, filed Aug. 4, 2023, the disclosures of each of which are incorporated by reference herein in their entireties for all purposes.

### BACKGROUND

Integrated circuits (ICs) sometimes include one-time-programmable (OTP) memories to provide non-volatile memory (NVM) in which data are not lost when the IC is powered off. One type of the OTP devices includes anti-fuse memories. The anti-fuse memories include a number of anti-fuse memory cells (or bit cells), whose terminals are disconnected before programming, and are shorted (e.g., connected) after the programming. The anti-fuse memories may be based on metal-oxide-semiconductor (MOS) technology. For example, an anti-fuse memory cell may include a programming MOS transistor (or MOS capacitor) and at least one reading MOS transistor coupled in series. A gate dielectric of the programming MOS transistor may be broken down to cause the gate and the source or drain of the programming MOS transistor to be interconnected. Depending on whether the gate dielectric of the programming MOS transistor is broken down, different data bits can be presented by the anti-fuse memory cell through reading a resultant current flowing through the programming MOS transistor and reading MOS transistor. The anti-fuse memories have the advantageous features of reverse-engineering proofing since the programming states of the anti-fuse cells cannot be determined through reverse engineering.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A illustrates a block diagram of an example layout for a bit cell of a memory array, in accordance with some embodiments.

FIG. 1B illustrates an example circuit diagram of a portion of memory array corresponding to the layout of FIG. 1A, in accordance with some embodiments.

FIG. 2A illustrates a cross-sectional layout diagram showing an example bit cell similar to that shown in FIGS. 1A and 1B having front side metal layers, in accordance with some embodiments.

FIG. 2B illustrates a cross-sectional layout diagram showing an example bit cell similar to that shown in FIGS. 1A and 1B having front-side and back-side metal layers, in accordance with some embodiments.

FIG. 3A illustrates a block diagram of an example layout for a bit cell of a memory array that includes voltage-relaxing devices, in accordance with some embodiments.

FIG. 3B illustrates an example circuit diagram of a portion of memory array corresponding to the layout of FIG. 3A, in accordance with some embodiments.

FIG. 4A illustrates a block diagram of an example layout for a bit cell of a memory array that includes multiple programming devices, in accordance with some embodiments.

FIG. 4B illustrates an example circuit diagram of a portion of memory array corresponding to the layout of FIG. 4A, in accordance with some embodiments.

FIG. 5A illustrates a block diagram of an example layout for a bit cell of a memory array that includes multiple pairs of voltage-relaxing devices, in accordance with some embodiments.

FIG. 5B illustrates an example circuit diagram of a portion of memory array corresponding to the layout of FIG. 5A, in accordance with some embodiments.

FIG. 6 illustrates a block diagram of an example layout for a bit cell of a memory array that includes dummy gate metal layers at an edge of a continuous active region, in accordance with some embodiments.

FIG. 7 illustrates a flow chart of an example method to fabricate the bit cells of FIGS. 1A-6B, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over, or on a second feature in the description that follows may include embodiments in which the first and second features are formed in direct contact and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” “top,” “bottom” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Bit cells are the smallest unit of data storage in a digital memory device, and may be manufactured using circuits that can store a single bit of information. Bit cells can be configured to represent one of two logical states, such as a logic low (e.g., logic 0) and logic high (e.g., logic 1). Bit cells are arranged in arrays to form memory chips, which are used in a wide variety of electronic devices and circuits that implement memory storage. Anti-fuse bit cells are a type of one-time programmable (OTP) bit cell that use the phenomenon of dielectric breakdown to store a single bit of information. Dielectric breakdown is a process in which an insulating material, such as a dielectric, is subjected to a voltage breaks it down such that it becomes conductive.

Traditional approaches to defining anti-fuse bit cells result in several issues. For example, near the edge of the oxide defined (OD) region of semiconductor material, transistors of bit cells suffer from the length of OD (LOD) effect. The LOD effect is a phenomenon in which the electrical characteristics of the transistors that make up the bit cell are affected by the distance between the transistor's gate and the edge of the OD region. The LOD effect can have a significant impact on the performance of memory cells, and is therefore undesirable. Additionally, traditional two-transistor anti-fuse bit cell layout structures are not area effective, resulting in wasted space on semiconductor dies.

Embodiments of the present disclosure utilize a continuous active OD region to define multiple-transistor bit cells to eliminate the LOD effect while improving device performance and reducing overall memory cell area. The techniques described herein utilize continuous active OD regions, upon which multiple bit cells can be defined. Each bit cell may include a pair of reading devices and a programming device defined therebetween. Dummy gate metal material layers may be provided near the edge of the continuous active region to eliminate the LOD effect, thereby improving device performance. In some implementations, voltage-relaxing devices may be included in the bit cell to reduce the effect of voltage stress during programming.

By having multiple pairs of reading transistors, various advantages as for reading/programming performance of the disclosed memory cell can be offered. For example, one of the reading transistors in each pair is symmetrically disposed on both sides of a corresponding one of the programming transistors. As such, upon any of the programming transistors being precedingly programmed, the symmetrically coupled reading transistors can significantly decrease the resistance value of an equivalent resistor coupled to the programmed resistor (e.g., the broken-down programming transistor).

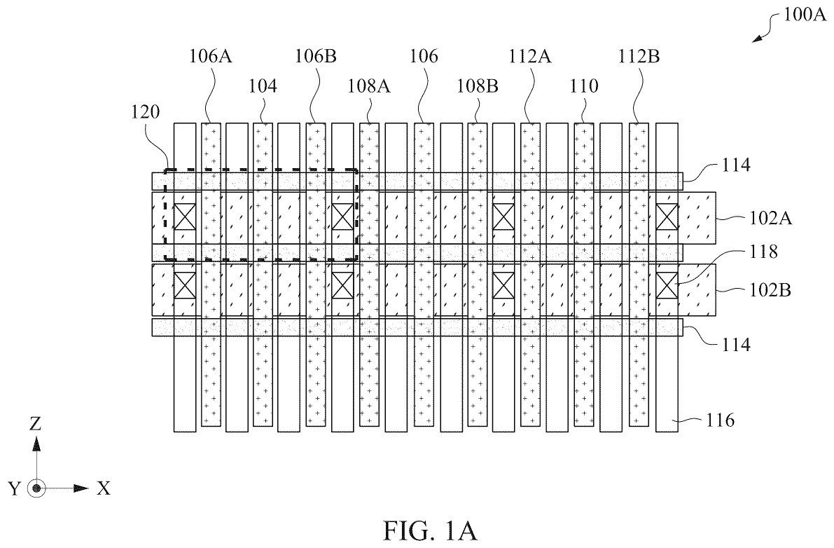

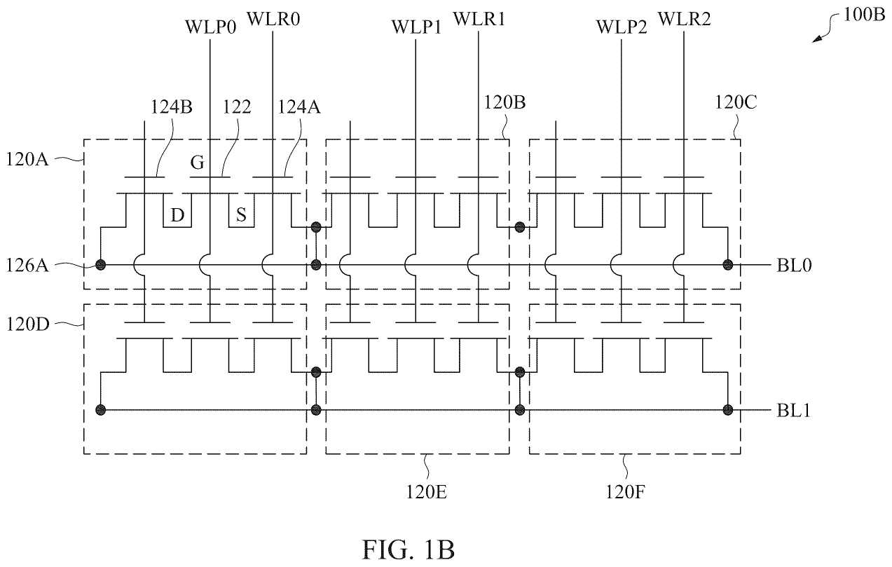

FIG. 1A illustrates a block diagram of an example layout 100A for a bit cell 120 of a memory array, in accordance with some embodiments. The example layout is a top down layout, in which multiple continuous active regions 102A and 102B are defined. The continuous active regions 102A and 102B may sometimes be referred to herein as the OD regions 102A and 102B. The OD regions 102A and 102B may include any suitable semiconductor material, for example, silicon. Alternatively, the OD regions 102A and 102B may include other elementary semiconductor material such as, for example, germanium. The continuous active regions 102A and 102B may also include a compound semiconductor such as silicon carbide, gallium arsenic, indium arsenide, and indium phosphide. The continuous active regions 102A and 102B may include an alloy semiconductor such as silicon germanium, silicon germanium carbide, gallium arsenic phosphide, and gallium indium phosphide. In one embodiment, the continuous active regions 102A and 102B includes an epitaxial layer. For example, the substrate may have an epitaxial layer overlying a bulk semiconductor. Furthermore, the continuous active regions 102A and 102B may include a semiconductor-on-insulator (SOI) structure.

As shown, each of the continuous active regions 102A and 102B extend along the X direction as single continuous regions of material, upon which programming devices and reading devices are defined (as described in further detail in connection with FIG. 1B). In the example shown in FIG. 1A, a bit cell 120 is formed by defining a first metal gate structure 104 for a first programming device (e.g., a programming transistor). Two additional metal gate structures 106A and 106B are formed to define reading devices (e.g., reading transistors) on either side of the programming device. Further details of the programming devices and the reading devices are described in connection with FIG. 1B. The first metal gate structure 104 and the reading metal gate structures 106A and 106B are defined along the direction Y, which is perpendicular to the direction X (e.g., along which the continuous active regions 102A and 102B extend). The gate metal may be separated from the continuous active regions 102A and 102B by a thin layer of a dielectric material, which in some implementations may be a high-k dielectric material. The gate structures described herein may therefore include multiple layers, for example, a gate dielectric layer and a gate metal. Any suitable material may be utilized to form the gate metal of the gate structures described herein, including, for example, polysilicon (PO), or any other metal material described herein.

As shown, the devices formed using the first metal gate structure 104 and the reading metal gate structures 106A and 106B share source/drain region(s). In this example, the programming device includes a source/drain region that is shared with a corresponding source/drain region of each of the reading devices. These source/drain regions may each be coupled to corresponding metal-to-diffusion layers 116, which may be used to route signals from the source/drain regions of the devices described herein to other circuits. Although not shown here, the first metal gate structure 104, the reading metal gate structures 106A and 106B, and/or any of the metal-to-diffusion layers 116 may be coupled to various interconnects to couple the bit cell 120 to other logical circuits. Signals used to activate (e.g., program and/or read from) the bit cell 120 are described in connection with FIG. 1B.

As shown, the continuous active regions 102A and 102B may include one or more conductive vias 118 defined therethrough, which in this example are shown as coupled to the outer source/drain nodes of the reading devices of each bit cell 120. The conductive vias 118, as well as any of the other metal materials described herein, including any gate metals, metal-to-diffusion layers, or interconnect metals, may be formed from, or may otherwise include, aluminum, tungsten, tungsten nitride, copper, cobalt, silver, gold, chrome, ruthenium, platinum, titanium, titanium nitride, tantalum, tantalum nitride, nickel, hafnium, and combinations thereof. The conductive vias may couple one or more of the source/drain nodes of the pairs of reading transistors with interconnects (e.g., a corresponding bit line), as described herein.

Although two continuous active regions 102A and 102B are shown here it, should be understood that any number of continuous active regions may be provided along the Z direction and formed according to the techniques described herein, to create memory arrays of any suitable size. As shown, various materials in the layout are shown as separated by the dielectric material 114 (e.g., an isolation structure). For example, a region of the dielectric material 114 electrically isolates the continuous active region 102A from the continuous active region 102B, thereby defining two rows of programming and reading devices as shown in this orientation. Additionally, the same regions of the dielectric material 114 may separate portions of the first metal gate structure 104 and the reading metal gate structures 106A and 106B, thereby isolating the gate structures (and devices formed therefrom) on the continuous active region 102A from those formed on the continuous active region 102B. In some implementations, the dielectric material 114 may isolate only the continuous active regions 102A and 102B from one another, rather than the first metal gate structure 304 and the reading metal gate structures 106A and 106B, enabling devices formed on each of the continuous active regions 102A and 102B to share gate metal. Example dielectric materials used to form the regions of the dielectric material may include, but are not limited to, oxide materials or other non-conductive materials (e.g., isolators).

In this example configuration, three bit cells 120 are shown on each of the continuous active regions 102A and 102B, thereby forming a total of six depicted bit cells 120. The first metal gate structure 104 and the reading metal gate structures 106A and 106B form the top left bit cell 120 on the continuous active region 102A and the bottom left bit cell on the continuous active region 102B. The second metal gate structure 106 and the second reading metal gate structures 108A and 108B form the top middle bit cell 120 on the continuous active region 102A and the bottom middle bit cell on the continuous active region 102B. The third metal gate structure 110 and the second reading metal gate structures 112A and 112B form the top right bit cell 120 on the continuous active region 102A and the bottom right bit cell on the continuous active region 102B. Although three bit cells 120 are shown on each of the continuous active regions 102A and 102B, it should be understood that any number of bit cells may be formed by providing corresponding metal gate layers, metal-to-diffusion layers, and conductive vias along the X direction. An example circuit diagram showing the electrical connections between each of the programming and reading devices of the bit cells 120 is shown in FIG. 1B.

Referring to FIG. 1B, illustrated is an example circuit diagram 100B of a portion of memory array shown via the layout 100A of FIG. 1A, in accordance with some embodiments. In the illustrated example of FIG. 1B, anti-fuse bit cells 120A, 120B, 120C, 120D, 120E, and 120F are shown. Although six anti-fuse memory cells 120A-F are shown, it should be appreciated that the memory array can have any number of anti-fuse memory cells, while remaining within the scope of present disclosure.

The bit cells 120A-120F can be arranged as an array, as shown in FIG. 1A. In FIG. 1B, the bit cells 120A, 120B, and 120C may be disposed in the same row (e.g., defined on the same continuous active region, such as the continuous active region 102A as shown in FIG. 1A) but in respectively different columns. The bit cells 120D, 120E, and 120F may be disposed in the same row (e.g., defined on the continuous active region 102B as shown in FIG. 1A) but in respectively different columns. With such a configuration, each of the bit cells can be operatively coupled to the access lines (e.g., WLP0, WLR0, WLP1, WLR1, WLP2, WLR2, BL0, BL1, etc.) in the corresponding row and column, respectively.

For example in FIG. 1B, the bit cell 120A and the bit cell 120D are operatively coupled to a first programming word line WLP0 and a first reading word line WLR0, and to a bit line BL0. The bit cell 120A is operatively coupled to a bit line BL0 and the bit cell 120D is operatively coupled to a bit line BL1. The bit cell 120B and the bit cell 120E are operatively coupled to a second programming word line WLP1 and a second reading word line WLR1. The bit cell 120B is operatively coupled to the bit line BL0 and the bit cell 120E is operatively coupled to the bit line BL1. The bit cell 120C and the bit cell 120F are operatively coupled to a third programming word line WLP2 and a third reading word line WLR2. The bit cell 120C is operatively coupled to the bit line BL0 and the bit cell 120F is operatively coupled to the bit line BL1.

Each of the access lines (e.g., WLP0, WLR0, WLP1, WLR1, WLP2, WLR2, BL0, BL1, etc.) may be operatively coupled to a corresponding I/O circuit that transmits corresponding signals to select bit cells 120 for programming or reading operations. These operations may be performed by applying predetermined patterns of logic selection to each of the access lines. The bit cell 120A is selected as a representative example in the following discussions of such operations.

As shown in FIG. 1B, the bit cell 120A includes a programming device 122 (sometimes referred to as a programming transistor 122), and a pair of reading devices 124A and 124B (sometimes referred to as a pair of reading transistors 124A and 124B). The programming transistor 122 is coupled to the reading transistors 124A and 124B, respectively, in series. One source/drain terminal of the programming transistor 122 is serially coupled to a source/drain terminal of one of the corresponding pair of reading transistors 124A and 124B; and the other source/drain terminal of the programming transistor 122 is serially coupled to a source/drain terminal of the other of the corresponding pair of reading transistors 124A and 124B.

The other source/drain terminals of the reading transistors 124A and 124B are commonly coupled to the nodes 126A and 126B, which connect said source/drain terminals to the bit line BL0. The nodes 126A and 126B may also be operatively connected to a source/drain terminal of a reading device of an adjacent bit cell 120. In this example, the node 126B is operatively coupled to a reading device of the bit cell 120B, as shown. As shown, the programming transistor 122 is gated by the programming line WLP0 (e.g., a gate terminal of the programming transistor 122 is coupled to WLP0). The reading transistors 124A and 124B are gated by the reading line WLR0 (e.g., respective gate terminals of the reading transistors 124A and 124B are coupled to the reading line WLR0).

Each of other bit cells (e.g., 120B, 120C, 120D, 120E, 120F) may be configured substantially similar as the bit cell 120A, and thus, the bit cells 120B through 120F are briefly described as follows. The bit cell 120D includes a bit cell that is also gated by the programming line WLP0. The bit cell 120B and the bit cell 120E include a programming device gated by the programming line WLP1. The bit cell 120C and the bit cell 120F each include programming devices gated by WLP2.

In some implementations, the programming/reading devices of the bit cells 120A-120F may include an n-type metal-oxide-semiconductor field-effect-transistor (n-type MOSFET) or sometimes referred to as an NMOS transistor. However, it should be understood that each of the programming/reading devices may include a p-type metal-oxide-semiconductor field-effect-transistor (p-type MOSFET), while remaining within the scope of present disclosure. It should be understood that the programming/reading devices described herein may include or otherwise be any type of transistor or switching device that is suitable for use in a bit cell.

To program the bit cell 120A, the reading transistors 124A and 124B are turned on by supplying a high enough voltage (e.g., a positive voltage corresponding to a logic high state) to their respective gate terminals via the reading line WLR0. Prior to, concurrently with or subsequently to the reading transistors 124A to 124B being turned on, a sufficiently high voltage (e.g., a breakdown voltage (VBD) which is sometimes referred to as a programming voltage) is applied to the programming line WLP0, and a low enough voltage (e.g., a positive voltage or ground voltage corresponding to a logic low state) is applied to the bit line BL0. The low voltage (applied on the bit line BL0) can be passed to the source/drain terminals of the programming device 122. As such, the programming voltage VBD can be concurrently present across the source terminal and the gate terminal of the programming transistor 122 and across the drain terminal and the gate terminal of the programming transistor 122. The breakdown voltage across these terminals causes the gate dielectric layer of the programming device 122 to break down.

After the gate dielectric layer of the programming device 122 is broken down, the electrical behavior of the portion of the gate dielectric layer interconnecting the gate terminal and its source/drain terminals is equivalently resistive. For example, such a portion of the gate dielectric layer of the programming transistor 122 may function as a resistor. Before the programming operation (e.g., before the gate dielectric layer of either of the programming transistors 122 is broken down), no conduction path exists between the bit line BL0 and the programming line WLP0, even if the reading devices 124A and 124B are turned on. After the programming operation has completed, a conduction path exists between the bit line BL0 and the programming line WLP0 (e.g., via the broken-down programming transistor 122, which operates as a resistor) when the reading devices 124A and 124B are turned on.

When the programming transistors 122 breaks down, a conduction path is established, and a sudden increase of voltage can be present on the source terminal and drain terminal of the programming transistor 122, which can induce a sudden increase of voltage on the bit line BL0. Accordingly, a voltage level at the source terminal and drain terminal of the programming transistor 122 can be increased such that the programming process on the programming transistor 122 can be automatically stopped (as a voltage drop across its gate and source terminals is decreased). Consequently, the bit cell 120A can be programmed to a first logic state or a second logic state.

In some embodiments, a reading process for the bit cell 120A can include concurrently applying a relatively low level of a voltage (sometimes referred to as a reading voltage) on the gate of the programming device 122. If the programming transistor 122 is broken down, an observable decrease of reading voltage may be present across the broken-down programming transistor 122. In contrast, if the programming transistor 122 is not broken down, the reading voltage applied on the non-broken-down programming transistor may remain substantially unchanged. In an example where the programming transistor 122 is broken down, an observable drop in the reading voltage applied on WLP0 may be detected. As a result, a logic state of the cell 120A can be determined accordingly. Similar approaches can be utilized to program any of the bit cells 120B to 120F, for example, by applying corresponding voltage signals to corresponding bit lines BL0 or BL1, to corresponding programming lines WLP0, WLP1, or WLP2, and to corresponding reading lines WLR0, WLR1, or WLR2, to break down a desired programming device.

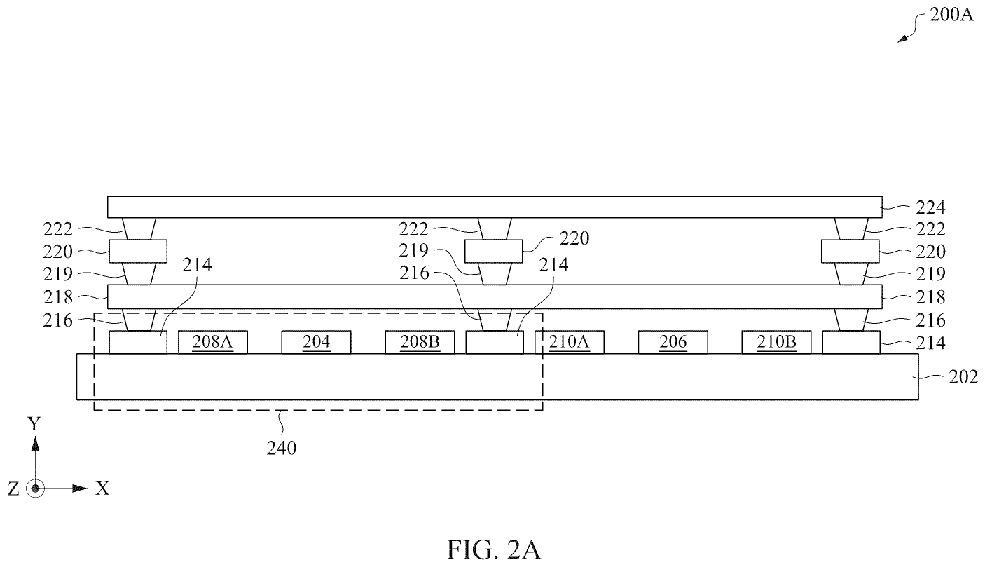

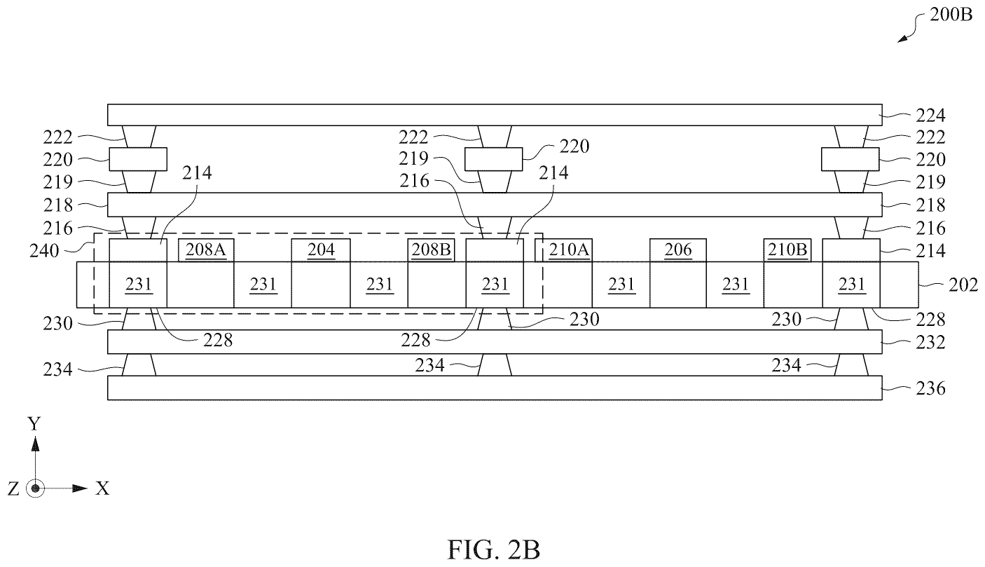

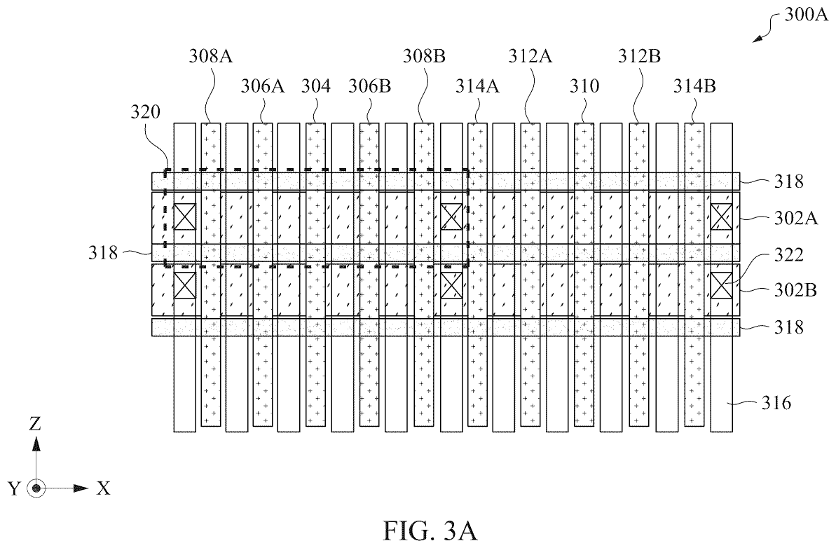

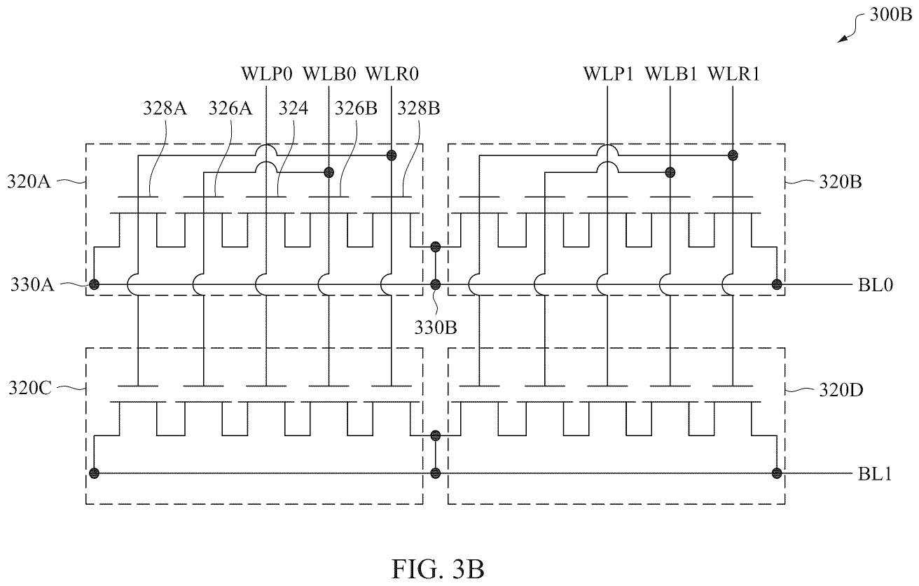

Referring to FIG. 2A, illustrated is a cross-sectional layout diagram 200A showing an example bit cells 240 similar to the bit cells 120 described in connection with FIGS. 1A and 1B. In this example, the cross-sectional layout diagram 200A shows front side metal layers formed to couple to the programming devices and the reading devices of the bit cells 240 defined on the continuous active region 202. In this example, the continuous active region 202 may be similar to one of the continuous active regions 102A or 102B, as described in connection with FIGS. 1A and 1B. Although two bit cells 240 are shown in this example, it should be understood that the continuous active region 202 may include any number of bit cells defined thereon. Likewise, the bit cells 240 defined on the continuous active region 202 may include any number of transistors, including bit cells having more than three transistors as described in connection with FIGS. 3A-5B

The bit cell 240 is shown as including a programming device gate structure 204, which may be similar to the gate structure 104 of FIG. 1A, which positioned between two reading device gate structures 208A and 208B, which may be similar to the pair of reading device gate structures 106A and 106B of FIG. 1A. As shown, a metal-to-diffusion regions 214 are formed on the continuous active region 202, such that one of the metal-to-diffusion regions 214 is formed on a source/drain terminal of the reading device having the reading device gate structure 208A and another of the metal-to-diffusion regions 214 is formed on a source/drain terminal of the reading device having the reading device gate structure 208B.

The metal-to-diffusion regions 214 are shown as coupled to corresponding conductive vias 216, which operatively couple the metal-to-diffusion regions 214 (and therefore the source/drain terminals of the reading devices). As designated by the curved lines in FIG. 2A, any number of layers of interconnect, each of which may include corresponding metal layers, may be coupled to one or more of the metal-to-diffusion regions 214 to achieve the desired logic for read and programming operations, as described herein. In this example, three metal layers 218, 220, and 224 are shown, each connected to various structures in the stack of materials forming the bit cells 240 by corresponding conductive vias. For example, the metal layer 218 is coupled to the metal-to-diffusion regions 214 by the conductive vias 216 and the metal layer 220, which is patterned in this cross sectional view to have several portions perpendicular to the metal layer 218, is coupled to the metal layer 216 using the conductive vias 219. Additionally, the third metal layer 224 is shown as coupled to the second metal layer 220 using the conductive vias 222.

Each of the three metal layers 218, 220, and 224 may be patterned such that they can operate as one or more of the corresponding bit lines BL0 and/or BL1 described in connection with FIGS. 1A-1B. Although not shown here, one or more metal layers may be provided to couple to (e.g., using one or more conductive vias) the programming device gate structure 204 to provide the programming voltage (e.g., VDB) or the read voltage. Likewise, although not shown here, one or more metal layers may be provided to couple to each of the gate structures 208A and 208B of the reading devices, to enable reading and programming for the device. In this example, each of the layers are formed via front-side metallization, in which metal layers are deposited on the front side (e.g., upward in the Y direction) of the device. An example that includes both front-side metallization and back-side metallization is shown in FIG. 2B.

FIG. 2B illustrates a cross-sectional layout diagram 200B, which depicts the memory device shown in FIG. 2A following back-side metallization. As shown, in addition to the front-side metal layers 218, 220, and 224 described in connection with FIG. 2A, the memory device is depicted including the back-side metal layers 232 and 236, which may be formed via a back-side metallization process. Each of the front-side metallization process used to form the front-side metal layers 218, 220, and 224 and the back-side metallization process used to form the back-side metal layers 232 and 236, may include cleaning, deposition, patterning, and planarization processes. Although not shown here for visual clarity, the whitespace gaps formed between each of the layers of material may include a dielectric material.

In this example, the first back-side metal layer 232 is operatively coupled to the metal-to-diffusion regions 214 by the backside vias (VB) 230. The backside vias 230 may be formed by creating conductive regions through the entirety of the continuous active region, which are coupled to the metal-to-diffusion regions 214, as shown. In this example, a second back-side metal layer 236 is operatively coupled to the metal-to-diffusion regions 214 using corresponding conductive vias 234. Although two back-side metal layers 232 and 236 are shown here, it should be understood that any number of back-side metal layers may be provided in order to implement desired logical functionality. In some implementations, back-side metal layers may not be utilized, with only front-side metallization being performed, as shown in FIG. 2A.

The cross-sectional layout 200B also shows regions of the continuous active region 202 corresponding to source/drain regions 231 (sometimes referred to herein as “epitaxial structures 231”). The source/drain regions 231 can include epitaxial structures that operate as source/drains of the corresponding transistors described herein. The source/drain regions 231 may be defined to form N-type or P-type devices. For example, N-type and p-type FETs may be formed by implanting different types of dopants to the source/drain regions 231 of the continuous active region 202 of the device to form the necessary junction(s). The source/drain regions 231 may be defined as the regions upon which the gate structures are not present. In one example, N-type devices can be formed by implanting arsenic (As) or phosphorous (P), and p-type devices can be formed by implanting boron (B).

In some embodiments, the continuous active region 202 is formed in a stack structure protruding from a major surface of a substrate. The stack can include a number of semiconductor nanostructures (e.g., nanosheets) extending along the X-direction and vertically separated from each other. Portions of the semiconductor structures in the stack that are overlaid by the gate structures (e.g., the gate structures 204, 208A-208B, etc.) remain, while other portions are replaced with a number of epitaxial structures 231. The remaining portions of the semiconductor structures (e.g., beneath the gate structures) can be configured as the channel of a corresponding transistor, the epitaxial structures coupled to both sides (or ends) of the remaining portions of the semiconductor structures can be configured as source/drain structures (or terminals) of the transistor, and a portion of the gate structure (e.g., the gate structures 204, 208A-208B) that overlays (e.g., straddles) the remaining portions of the semiconductor structures can be configured as a gate structures (or terminal) of the transistor.

For example in FIG. 2B, the portion of the continuous active region 202 that is overlaid by the gate structure 204 may include a number of nanostructures vertically separated from each other, which can function as the channel of a first transistor. The portions of the continuous active region 202 that are disposed on opposite sides of the gate structure 204 are replaced with epitaxial structures 231, as shown. Furthering this example, such epitaxial structures 231 can function as source/drain terminals (“D” and “S” of FIG. 1B) of the programming transistor 122. The gate structure can function as a gate terminal (“G” of FIG. 1B) of the programming transistor 122.

Referring to FIG. 3A, illustrated is a block diagram of an example layout 300A for a bit cell 320 of a memory array that includes voltage-relaxing devices, in accordance with some embodiments. Similar to the layout shown in FIG. 1A, the layout 300A is a top-down layout, in which multiple continuous active regions 302A and 302B are defined. The continuous active regions 302A and 302B may sometimes be referred to herein as the OD regions 302A and 302B. The continuous active regions 302A and 302B may be similar to the continuous active regions 102A and 102B of FIG. 1A, and may include any suitable semiconductor material, for example, silicon, or any other type of semiconductor material described herein.

As shown, each of the continuous active regions 302A and 302B extend along the X direction as single continuous regions of material, upon which programming devices and reading devices are defined (as described in further detail in connection with FIG. 3B). In the example shown in FIG. 3A, a bit cell 320 is formed by defining a first metal gate structure 304 for a first programming device (e.g., a programming transistor). Two gate structures 306A and 306B are formed to define voltage-relaxing devices (e.g., voltage-relaxing transistors) on either side of the programming device. Additional metal gate structures 308A and 308B are also formed to define reading devices (e.g., reading transistors) on either side of the voltage-relaxing devices, as shown, such that the voltage-relaxing devices are each positioned between a respective reading device and the programing device. Further details of the programming devices, the voltage-relaxing devices, and the reading devices are described in connection with FIG. 3B.

The first metal gate structure 304, the voltage-relaxing gate structures 306A and 306B, and the reading metal gate structures 308A and 308B are defined along the direction Y, which is perpendicular to the direction X (e.g., along which the continuous active regions 302A and 302B extend). The gate metal may be separated from the continuous active regions 302A and 302B by a thin layer of a dielectric material, which in some implementations may be a high-k dielectric material. The gate structures described herein may therefore include multiple layers, for example, a gate dielectric layer and a gate metal. Any suitable material may be utilized to form the gate metal of the gate structures described herein, including, for example, PO, or any other metal material described herein.

As shown, the devices formed using the first metal gate structure 304 (sometimes referred to as the programming metal gate structure 304) and voltage-relaxing metal gate structures 306A and 306B share source/drain region(s). Likewise, each of the voltage-relaxing devices share a respective source/drain region with an adjacent one of the reading devices. As shown, the source/drain regions of each of the voltage-relaxing devices, as well as each of the reading devices, may be coupled to a corresponding metal-to-diffusion layer 316. The metal-to-diffusion layers 316 may be similar to the metal-to-diffusion layer 116 of FIG. 1A and may be used to route signals from the source/drain regions of the devices described herein to other circuits. Although not shown here, the programming metal gate structure 304, the voltage-relaxing metal gate structure 306A and 306B, and the reading metal gate structures 308A and 308B, and/or any of the metal-to-diffusion layers 316 may be coupled to various interconnects to couple the bit cell 320 to other logical circuits. Signals used to activate (e.g., program and/or read from) the bit cell 320 are described in connection with FIG. 3B.

As shown, the continuous active regions 302A and 302B may include one or more conductive vias 322 defined therethrough, which in this example are shown as coupled to the outer source/drain nodes of the reading devices of each bit cell 320. The conductive vias 322, as well as any of the other metal materials described herein, including any gate metals, metal-to-diffusion layers, or interconnect metals, may be formed from, or may otherwise include, aluminum, tungsten, tungsten nitride, copper, cobalt, silver, gold, chrome, ruthenium, platinum, titanium, titanium nitride, tantalum, tantalum nitride, nickel, hafnium, and combinations thereof.

The conductive vias may couple one or more of the source/drain nodes of the pairs of reading transistors with interconnects (e.g., a corresponding bit line), as described herein.

Although two continuous active regions 302A and 302B are shown here it, should be understood that any number of continuous active regions that extend continuously along the X direction may be provided along the Z direction, as shown, and may be formed according to the techniques described herein, to create memory arrays of any suitable size. As shown, various materials in the layout 300A are shown as separated by the dielectric material 318. For example, a region of the dielectric material 318 electrically isolates the continuous active region 302A from the continuous active region 302B, thereby defining two rows of programming and reading devices as shown in this orientation. Additionally, the same regions of the dielectric material 318 may separate portions of the first metal gate structure 304, the voltage-relaxing gate structures 306A and 306B, and the reading metal gate structures 308A and 308B, thereby isolating the gate structures (and devices formed therefrom) on the continuous active region 302A from those formed on the continuous active region 302B. In some implementations, the dielectric material 318 may isolate only the continuous active regions 302A and 302B from one another, rather than the first metal gate structure 304, the voltage-relaxing gate structures 306A and 306B, and the reading metal gate structures 308A and 308B, enabling devices formed on each of the continuous active regions 302A and 302B to share gate metal.

In this example configuration, two bit cells 320 are shown on each of the continuous active regions 302A and 302B, thereby forming a total of four depicted bit cells 320. The first metal gate structure 304, the voltage-relaxing metal gate structures 306A and 306B, and the reading metal gate structures 308A and 308B form the top left bit cell 320 on the continuous active region 302A and the bottom left bit cell on the continuous active region 302B. The second metal gate structure 310, the second voltage-relaxing gate structures 312A and 312B, and the second reading metal gate structures 314A and 314B form the top right bit cell 320 on the continuous active region 302A and the bottom right bit cell on the continuous active region 302B. Although two bit cells 320 are shown on each of the continuous active regions 302A and 302B, it should be understood that any number of bit cells may be formed by providing corresponding metal gate layers, metal-to-diffusion layers, and conductive vias along the X direction. An example circuit diagram showing the electrical connections between each of the programming and reading devices of the bit cells 320 is shown in FIG. 3B.

Referring to FIG. 3B, illustrates an example circuit diagram 300B of a portion of memory array corresponding to the layout 300A of FIG. 3A, in accordance with some embodiment. In the illustrated example of FIG. 3B, anti-fuse bit cells 320A, 320B, 320C, and 320D are shown. Although four anti-fuse memory cells 320A-D are shown, it should be appreciated that the memory array can have any number of anti-fuse memory cells, while remaining within the scope of present disclosure.

The bit cells 320A-320D can be arranged as an array, as shown in FIG. 3A. In FIG. 3B, the bit cells 320A and 320B may be disposed in the same row (e.g., defined on the same continuous active region, such as the continuous active region 302A as shown in FIG. 3A) but in respectively different columns. The bit cells 320C and 320D may be disposed in the same row (e.g., defined on the continuous active region 302B as shown in FIG. 3A) but in respectively different columns. With such a configuration, each of the bit cells can be operatively coupled to the access lines (e.g., WLP0, WLB0, WLR0, WLP1, WLB1 WLR1, BL0, BL1, etc.) in the corresponding row and column, respectively.

For example in FIG. 3B, the bit cell 320A and the bit cell 320C are operatively coupled to a first programming word line WLP0, a first voltage-relaxing word line WLB0, and a first reading word line WLR0, and to a bit line BL0. The bit cell 320A is operatively coupled to a bit line BL0 and the bit cell 320C is operatively coupled to a bit line BL1. The bit cell 320B and the bit cell 320C are operatively coupled to a second programming word line WLP1, a second voltage-relaxing word line WLB1, and a second reading word line WLR1. The bit cell 320B is operatively coupled to the bit line BL0 and the bit cell 320C is operatively coupled to the bit line BL1.

Each of the access lines (e.g., WLP0, WLB0, WLR0, WLP1, WLB1 WLR1, BL0, BL1, etc.) may be operatively coupled to a corresponding I/O circuit that transmits corresponding signals to select bit cells 320 for programming or reading operations. These operations may be performed by applying predetermined patterns of logic selection to each of the access lines. The bit cell 320A is selected as a representative example in the following discussions of such operations.

As shown in FIG. 3B, the bit cell 320A includes a programming device 324 (sometimes referred to as a programming transistor 324), a pair of voltage-relaxing devices 326A and 326B (sometimes referred to as a pair of voltage-relaxing transistors 326A and 326B), and a pair of reading devices 328A and 328B (sometimes referred to as a pair of reading transistors 328A and 328B). The programming transistor 324 and the voltage-relaxing transistors 326A and 326B are connected in series, as shown, which themselves are coupled to the reading transistors 328A and 328B, respectively, in series.

One source/drain terminal of the programming transistor 324 is serially coupled to a source/drain terminal of one of the corresponding pair of voltage-relaxing transistors 326A and 326B; and the other source/drain terminal of the programming transistor 324 is serially coupled to a source/drain terminal of the other of the corresponding pair of voltage-relaxing transistors 328A and 328B. One source/drain terminal of the voltage-relaxing transistor 326A is serially coupled to a source/drain terminal of the reading transistor 328A; and the source/drain terminal of the voltage-relaxing transistor 326B is serially coupled to a source/drain terminal of the reading transistor 328B, as shown.

The other source/drain terminals of the reading transistors 328A and 328B are commonly coupled to the nodes 330A and 330B, which connect said source/drain terminals to the bit line BL0. The nodes 330A and 330B may also be operatively connected to a source/drain terminal of a reading device of an adjacent bit cell 320. In this example, the node 330B is operatively coupled to a reading device of the bit cell 320B, as shown. As shown, the programming transistor 324 is gated by the programming line WLP0 (e.g., a gate terminal of the programming transistor 324 is coupled to WLP0). The voltage-relaxing transistors 326A and 326B are gated by the voltage-relaxing word line WLB0 (e.g., respective gate terminals of the voltage-relaxing transistors 326A and 326B are coupled to the voltage-relaxing word line WLB0). The reading transistors 328A and 328B are gated by the reading line WLR0 (e.g., respective gate terminals of the reading transistors 328A and 328B are coupled to the reading line WLR0).

Each of other bit cells (e.g., 320B, 320C, 320D) may be configured substantially similar as the bit cell 320A, and thus, the bit cells 320B through 320D are briefly described as follows. The bit cell 320C includes a bit cell that is also gated by the programming line WLP0. The bit cell 320B and the bit cell 320D include a programming device gated by the programming line WLP1.

In some implementations, the programming devices, voltage-relaxing devices, and reading devices of the bit cells 320A-320D may include an n-type metal-oxide-semiconductor field-effect-transistor (n-type MOSFET) or sometimes referred to as an NMOS transistor. However, it should be understood that each of the programming/reading devices may include a p-type metal-oxide-semiconductor field-effect-transistor (p-type MOSFET), while remaining within the scope of present disclosure. It should be understood that the programming/reading devices described herein may include or otherwise be any type of transistor or switching device that is suitable for use in a bit cell.

To program the bit cell 320A, the voltage-relaxing transistors 326A and 326B and the reading transistors 328A and 328B are turned on by supplying a high enough voltage (e.g., a positive voltage corresponding to a logic high state) to their respective gate terminals via voltage-relaxing word line WLB0 and the reading word line WLR0. Prior to, concurrently with, or subsequently to the voltage-relaxing transistors 326A and 326B and the reading transistors 328A to 328B being turned on, a sufficiently high voltage (e.g., VBD) is applied to the programming line WLP0, and a low enough voltage (e.g., a positive voltage or ground voltage corresponding to a logic low state) is applied to the bit line BL0.

The inclusion of the pair of voltage-relaxing transistors 326A and 326B between the programming resistor 324 and the pair of reading transistors 328A and 328B reduce overall high-voltage stress across each device during programming operations. The low voltage (applied on the bit line BL0) can be passed to the source/drain terminals of the programming device 324. As such, the programming voltage VBD can be concurrently present across the source terminal and the gate terminal of the programming transistor 324 and across the drain terminal and the gate terminal of the programming transistor 324. The breakdown voltage across these terminals causes the gate dielectric layer of the programming device 324 to break down, causing it to behave as a resistor, as described in connection with FIG. 1A.

As described herein, when the programming transistors 324 breaks down, a conduction path is established, and a sudden increase of voltage can be present on the source terminal and drain terminal of the programming transistor 324, which can induce a sudden increase of voltage on the bit line BL0. Accordingly, a voltage level at the source terminal and drain terminal of the programming transistor 324 can be increased such that the programming process on the programming transistor 324 can be automatically stopped (as a voltage drop across its gate and source terminals is decreased). Consequently, the bit cell 320A can be programmed to a first logic state or a second logic state.

In some embodiments, a reading process for the bit cell 320A can include concurrently applying a relatively low level of a voltage (sometimes referred to as a reading voltage) on the gate of the programming device 324. If the programming transistor 324 is broken down, an observable decrease of reading voltage may be present across the broken-down programming transistor 324. In contrast, if the programming transistor 324 is not broken down, the reading voltage applied on the non-broken-down programming transistor may remain substantially unchanged. In an example where the programming transistor 324 is broken down, an observable drop in the reading voltage applied on WLP0 may be detected. As a result, a logic state of the cell 320A can be determined accordingly. Similar approaches can be utilized to program any of the bit cells 320B to 320D, for example, by applying corresponding voltage signals to corresponding bit lines BL0 or BL1, to corresponding programming lines WLP0 or WLP1, and to corresponding voltage-relaxing lines WLB0 or WLB1, and to corresponding reading lines WLR0 or WLR1, to break down a desired programming device.

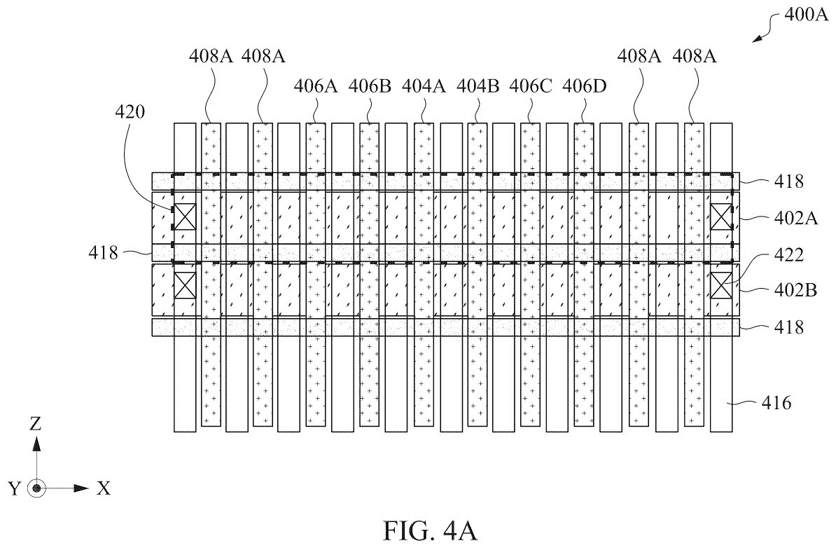

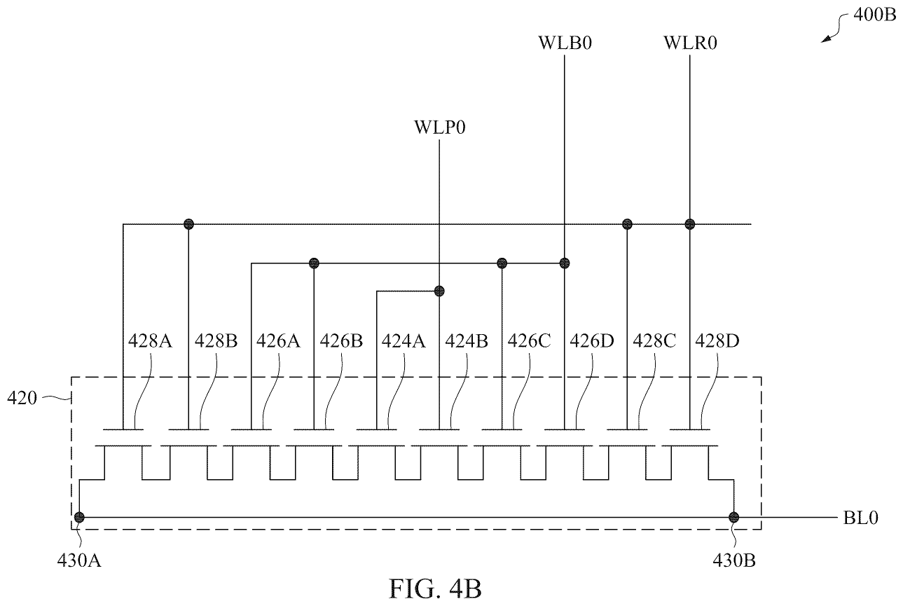

Referring to FIG. 4A, illustrated is a block diagram of an example layout 400A for an example bit cell 420 of a memory array that includes multiple programming devices, in accordance with some embodiments. Similar to the layout shown in FIGS. 1A and 3A, the layout 400A is a top-down layout, in which multiple continuous active regions 402A and 402B are defined. The continuous active regions 402A and 402B may sometimes be referred to herein as the OD regions 402A and 402B. The continuous active regions 402A and 402B may be similar to the continuous active regions 102A and 102B of FIG. 1A, and may include any suitable semiconductor material, for example, silicon, or any other type of semiconductor material described herein.

As described in connection with FIGS. 1A and 3A, each of the continuous active regions 402A and 402B extend along the X direction as single continuous regions of material, upon which programming devices and reading devices are defined (as described in further detail in connection with FIG. 4B). In the example shown in FIG. 4A, a bit cell 420 is formed by defining metal gate structures 404A and 404B, each corresponding to a respective programming device (e.g., programming transistors that share a source/drain region and are connected in series). Four voltage-relaxing gate structures 406A, 406B, 406C, and 406D are formed to define a set of four voltage-relaxing devices (e.g., four voltage-relaxing transistors) on either side of the two programming devices. Four additional reading gate structures 408A, 408B, 408C, and 408D are also formed to define four reading devices (e.g., reading transistors) on either side of the respective pairs of voltage-relaxing devices that surround the pair of programming devices, as shown, such that two voltage-relaxing devices are each positioned between a respective reading device and the programing device. Further details of the programming devices, the voltage-relaxing devices, and the reading devices are described in connection with FIG. 4B.

The configuration shown in FIG. 4A is similar in structure to the example shown in FIG. 1A, except that two devices are used for each device defined in the configuration in the layout 100A shown in FIG. 1A. For example, the layout 400A includes dielectric material 418, which may be similar to the dielectric material 114 of FIG. 1A and can electrically isolate the continuous active regions 402A and 402B from one another and from other components of the circuit. Additionally, programming devices, voltage-relaxing devices, and reading devices defined by the programming gate structures 404A-404B, the voltage-relaxing gate structures 406A-406D, and the reading gate structures 408A-408D, respectively, each include corresponding source/drain structures.

In this example, each of the source/drain structures is shown as being coupled to a respective metal-to-diffusion layer 416, which may be similar to the metal-to-diffusion layers 116 of FIG. 1A. Each of the continuous active regions 102A and 102B may include one or more conductive vias 422 defined therethrough, which in this example are shown as coupled to the outer source/drain nodes of the outermost reading devices of each bit cell 120. Although two continuous active regions 102A and 102B are shown here it, should be understood that any number of continuous active regions may be provided along the Z direction and formed according to the techniques described herein, to create memory arrays of any suitable size. Likewise, any number of bit cells 420 may be defined along the continuous active regions 402A and 402B by providing corresponding gate structures, metal-to-diffusion layers, and conductive vias in a similar pattern to that shown in the layout 400A. In this example, two bit cells 420 are shown, one formed on the continuous active region 402A and another formed on the continuous active region 402B. An example circuit diagram showing the electrical connections between each of the programming and reading devices of the bit cells 120 is shown in FIG. 1B.

Referring to FIG. 4B, illustrated an example circuit diagram 400B of a portion of memory array corresponding to the layout 400A of FIG. 4A, in accordance with some embodiments. In the illustrated example of FIG. 4B, one anti-fuse bit cell 420 is shown, omitting the second anti-fuse bit cell shown in the layout 400A for visual clarity. Although one anti-fuse bit cell 420 is shown, it should be appreciated that the memory array can have any number of anti-fuse bit cells, while remaining within the scope of present disclosure.

The bit cell 420 may be defined as part of a memory array, in a corresponding row and column relative to other bit cells. With such a configuration, each of the bit cells can be operatively coupled to the access lines in the corresponding row and column, respectively. In FIG. 4B, the bit cell 420 is operatively coupled to a programming word line WLP0, a voltage-relaxing word line WLB0, and a reading word line WLR0, and to a bit line BL0. Each of the access lines (e.g., WLP0, WLB0, WLR0, BL0, etc.) may be operatively coupled to a corresponding I/O circuit that transmits corresponding signals to select bit cells 420 for programming or reading operations. These operations may be performed by applying predetermined patterns of logic selection to each of the access lines.

The bit cell 420 includes two programming devices 424A (sometimes referred to as a programming transistor 424A), two pairs of voltage-relaxing devices 426A, 426B, 426C, and 426D (sometimes referred to as the voltage-relaxing transistors 426A, 426B, 426C, and 426D), and two pairs of reading devices 428A, 428B, 428C, and 428D (sometimes referred to as the reading transistors 428A, 428B, 428C, and 428D). The pair of programming transistors 424A and 424B are connected in series. The first programming transistor 424A is coupled in series with the first pair of voltage-relaxing transistors 426A and 426B in series, as shown, and the second programming transistor 424B is coupled in series with the second pair of voltage-relaxing transistors 426C and 426D. The first pair of voltage-relaxing transistors 426A-426B is coupled to a first pair of reading transistors 428A-428B, in series, and the second pair of voltage-relaxing transistors 426C-426D is coupled to a second pair of reading transistors 428C-428D, in series, as shown. Each of said device devices share source/drain terminals as shown.

The outer source/drain terminals of the reading transistors 428A and 428D are commonly coupled to the nodes 430A and 430B, which connect said source/drain terminals to the bit line BL0. The nodes 430A and 430B may also be operatively connected to a source/drain terminal of a reading device of an adjacent bit cell 420. As shown, the programming transistors 424A and 424B are gated by the programming line WLP0 (e.g., gate terminals of the programming transistors 424A and 424B are coupled to WLP0). The voltage-relaxing transistors 426A, 426B, 426C, and 426D are gated by the voltage-relaxing word line WLB0 (e.g., respective gate terminals of the voltage-relaxing transistors 426A, 426B, 426C, and 426D are coupled to the voltage-relaxing word line WLB0). The reading transistors 428A, 428B, 428C, and 428D are gated by the reading line WLR0 (e.g., respective gate terminals of the reading transistors 428A, 428B, 428C, and 428D are coupled to the reading line WLR0).

In some implementations, the programming devices, voltage-relaxing devices, and reading devices of the bit cells 320A-320D may include an n-type metal-oxide-semiconductor field-effect-transistor (n-type MOSFET) or sometimes referred to as an NMOS transistor. However, it should be understood that each of the programming/reading devices may include a p-type metal-oxide-semiconductor field-effect-transistor (p-type MOSFET), while remaining within the scope of present disclosure. It should be understood that the programming/reading devices described herein may include or otherwise be any type of transistor or switching device that is suitable for use in a bit cell.

To program the bit cell 420, operations similar to those described in connection with FIG. 1B may be performed, with a programming voltage applied to the programming line WLP0, while turning on the voltage-relaxing transistors 426A-426D and the reading transistors 428A-428D, while a logic low state is applied to the bit line BL0. This causes the programming transistors 424A and 424B to break down and change their electrical behavior to behave as resistors. Reading processes for the bit cell 420 may be similar to those described in connection with FIG. 1A, and can include concurrently applying a relatively low level of a voltage (sometimes referred to as a reading voltage) on the gate of the programming devices 424A and 424B.

In some implementations, the programming voltage applied to WLP0 during a programming operation may be between about 3V to about 5V, and the reading voltage applied to WLP0 during a reading operation may be between about 0.9V to about 1.5V. In some implementations, the programming voltage applied to WLR0 during a programming operation may be between about 0.9 to about 1.5V, and the reading voltage applied to WLR0 during a reading operation may be between about 0.5V to about 0.9V. The voltage applied to WLB0 during a programming operation may be between the voltage applied to WLP0 and WLR0, and may be between about 1V to about 4.5V. In some implementations, during a read operation, the reading voltage applied to WLB0 may be between about 0.5V to about 0.9V. If a particular line is unselected (e.g., the bit cell 420 is not being programmed or read), the unselect voltage applied to the lines may be less than about 0.5V, in some implementations.

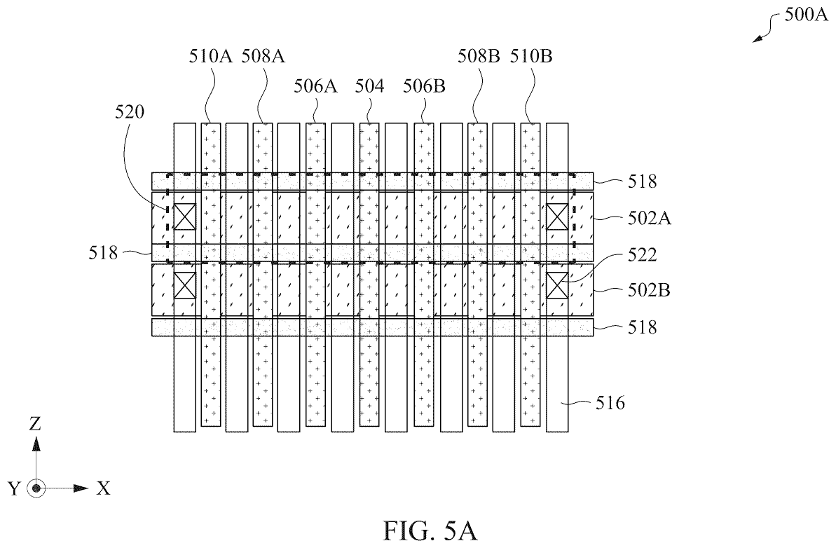

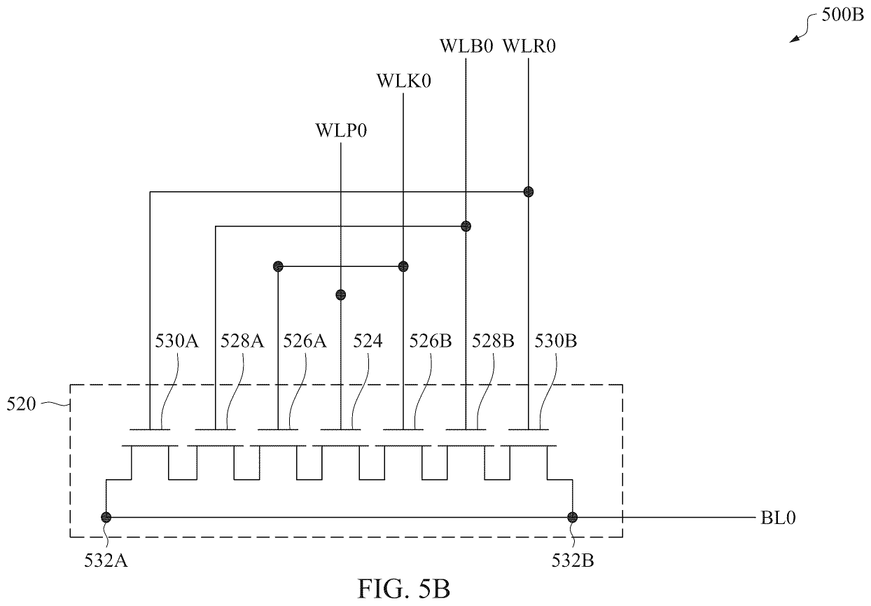

Referring to FIG. 5A, illustrated is a block diagram of an example layout 500A for a bit cell 520 of a memory array that includes multiple pairs of voltage-relaxing devices and a single programming device, in accordance with some embodiments. Similar to the layout shown in FIGS. 1A, 3A, and 4A the layout 500A is a top-down layout, in which multiple continuous active regions 502A and 502B are defined. The continuous active regions 502A and 502B may sometimes be referred to herein as the OD regions 502A and 502B. The continuous active regions 502A and 502B may be similar to the continuous active regions 102A and 102B of FIG. 1A, and may include any suitable semiconductor material, for example, silicon, or any other type of semiconductor material described herein.

As described in connection with FIGS. 1A, 3A, and 4A, each of the continuous active regions 502A and 502B extend along the X direction as single continuous regions of material, upon which programming devices and reading devices are defined (as described in further detail in connection with FIG. 5B). In the example shown in FIG. 5A, a bit cell 520 is formed by defining a first metal gate structure 504 for a first programming device (e.g., a programming transistor). Two first voltage-relaxing gate structures 506A and 506B are formed to define a first pair of voltage-relaxing devices (e.g., first voltage-relaxing transistors) on either side of the programming device. Two second voltage-relaxing gate structures 508A and 508B are formed to define a second pair of voltage-relaxing devices (e.g., second voltage-relaxing transistors) on either side of the programming device, with each positioned in series with a respective one of the first pair of voltage-relaxing devices, as shown. Additional metal gate structures 510A and 510B are also formed to define reading devices (e.g., reading transistors) on either side of the second voltage-relaxing devices, as shown, such that a first voltage-relaxing device and a corresponding second voltage-relaxing device are each positioned between a respective reading device and the programing device. Further details of the programming devices, the voltage-relaxing devices, and the reading devices are described in connection with FIG. 5B.

The programming gate structure 504, the first voltage-relaxing gate structures 506A and 506B, the second voltage-relaxing gate structures 508A and 508B, and the reading metal gate structures 510A and 510B are defined along the direction Y, which is perpendicular to the direction X (e.g., along which the continuous active regions 502A and 502B extend). In this example, the gate structures extend across both the continuous active region 502A and the continuous active region 502B. The gate metal may be separated from the continuous active regions 502A and 502B by a thin layer of a dielectric material, which in some implementations may be a high-k dielectric material. The gate structures described herein may therefore include multiple layers, for example, a gate dielectric layer and a gate metal. Any suitable material may be utilized to form the gate metal of the gate structures described herein, including, for example, PO, or any other metal material described herein.

As shown, the devices formed using the programming gate structure 504 (sometimes referred to as the programming gate structure 504) and the first voltage-relaxing gate structures 506A and 506B share source/drain region(s). Likewise, each of the first voltage-relaxing devices share a respective source/drain region with an adjacent one of the second voltage-relaxing devices. Each of the second voltage devices share a respective source/drain region with an adjacent one of the reading devices. As shown, the source/drain regions of each of the first and second voltage-relaxing devices, as well as each of the reading devices, may be coupled to a corresponding metal-to-diffusion layer 516. The metal-to-diffusion layers 516 may be similar to the metal-to-diffusion layer 116 of FIG. 1A and may be used to route signals from the source/drain regions of the devices described herein to other circuits. Although not shown here, the programming metal gate structure 504, the first voltage-relaxing metal gate structures 506A and 506B, the second voltage-relaxing metal gate structures 508A and 508B, and the reading metal gate structures 510A and 510B, and/or any of the metal-to-diffusion layers 516 may be coupled to various interconnects to couple the bit cell 520 to other logical circuits. Signals used to activate (e.g., program and/or read from) the bit cell 520 are described in connection with FIG. 5B.

The continuous active regions 502A and 502B may include one or more conductive vias 522 defined therethrough, which in this example are shown as coupled to the outer source/drain nodes of the reading devices of each bit cell 520. The conductive vias 522, as well as any of the other metal materials described herein, including any gate metals, metal-to-diffusion layers, or interconnect metals, may be formed from, or may otherwise include, aluminum, tungsten, tungsten nitride, copper, cobalt, silver, gold, chrome, ruthenium, platinum, titanium, titanium nitride, tantalum, tantalum nitride, nickel, hafnium, and combinations thereof. The conductive vias may couple one or more of the source/drain nodes of the pairs of reading transistors with interconnects (e.g., a corresponding bit line), as described herein.

As shown, various materials in the layout 500A are shown as separated by the dielectric material 518. For example, a region of the dielectric material 518 electrically isolates the continuous active region 502A from the continuous active region 502B, thereby defining two rows of programming and reading devices as shown in this orientation. Additionally, the same regions of the dielectric material 518 may separate portions of the programming gate structure 504, the first voltage-relaxing gate structures 506A and 506B, second voltage-relaxing gate structures 508A and 508B, and the reading metal gate structures 508A and 508B, thereby isolating the gate structures (and devices formed therefrom) on the continuous active region 502A from those formed on the continuous active region 502B. In some implementations, the dielectric material 518 may isolate only the continuous active regions 502A and 502B from one another, rather than the programming gate structure 504, the first voltage-relaxing gate structures 506A and 506B, second voltage-relaxing gate structures 508A and 508B, and the reading metal gate structures 508A and 508B, enabling devices formed on each of the continuous active regions 502A and 502B to share gate metal. An example circuit diagram showing the electrical connections between each of the programming and reading devices of the bit cells 520 is shown in FIG. 5B.

Referring to FIG. 5B, illustrated is an example circuit diagram 500B of a portion of memory array corresponding to the layout of FIG. 5A, in accordance with some embodiments. In the illustrated example of FIG. 5B, one anti-fuse bit cell 520 is shown, omitting the second anti-fuse bit cell shown in the layout 500A for visual clarity. Although one anti-fuse bit cell 520 is shown, it should be appreciated that the memory array can have any number of anti-fuse bit cells, while remaining within the scope of present disclosure.

The bit cell 520 may be defined as part of a memory array, in a corresponding row and column relative to other bit cells. With such a configuration, each of the bit cells can be operatively coupled to the access lines in the corresponding row and column, respectively. In FIG. 5B, the bit cell 520 is operatively coupled to a programming word line WLP0, a first voltage-relaxing word line WLB0, a second voltage-relaxing word line WLK0, and a reading word line WLR0, and to a bit line BL0. Each of the access lines (e.g., WLP0, WLB0, WLK0, WLR0, BL0, etc.) may be operatively coupled to a corresponding I/O circuit that transmits corresponding signals to select bit cells 520 for programming or reading operations. These operations may be performed by applying predetermined patterns of logic selection to each of the access lines.

The bit cell 520 includes a programming device 524 (sometimes referred to as a programming transistor 524), a first pair of voltage-relaxing devices 526A and 526B (sometimes referred to as the first voltage-relaxing transistors 526A and 526B), a second pair of voltage-relaxing devices 528A and 528B (sometimes referred to as the second voltage-relaxing transistors 528A and 528B), and a pair of reading devices 530A and 530B (sometimes referred to as the reading transistors 530A and 530B). The programming transistor 524 is coupled in series with the first pair of voltage-relaxing transistors 526A and 526B in series, as shown, such that the source/drain nodes of the programming transistor 524 are shared with a respective one of each of the first pair of voltage-relaxing transistors 526A and 526B.

The other source/drain nodes of each of the first pair of voltage-relaxing transistors 526A and 526B is coupled in series with the second pair of voltage-relaxing transistors 528A and 528B, such that a respective one of the source/drain nodes of each of the second pair of voltage-relaxing transistors 528A and 528B is shared with a respective one of the first pair of voltage-relaxing transistors 526A and 526B. The other source/drain node of the second pair of voltage-relaxing transistors 528A-528B is coupled to a corresponding source/drain of a respective one of the pair of reading transistors 530A-530B, in series, as shown. As such, the programming device 524, the first pair of voltage-relaxing devices 526A-526B, the second pair of voltage-relaxing devices 528A-528B, and the pair of reading devices 530A-530B are connected in series via corresponding source/drain terminals, as shown.

The outer source/drain terminals of the reading transistors 530A and 530B are commonly coupled to the nodes 532A and 532B, which connect said source/drain terminals to the bit line BL0. The nodes 532A and 532B may also be operatively connected to a source/drain terminal of a reading device of an adjacent bit cell 520. As shown, the programming transistor 524 is gated by the programming line WLP0 (e.g., a gate terminal of the programming transistor 524 is coupled to WLP0). The first pair of voltage-relaxing transistors 526A and 526B are gated by the voltage-relaxing word line WLB0 (e.g., respective gate terminals of the first voltage-relaxing transistors 526A and 526B are coupled to the voltage-relaxing word line WLB0). The second pair of voltage-relaxing transistors 528A and 528B are gated by the voltage-relaxing word line WLK0 (e.g., respective gate terminals of the second voltage-relaxing transistors 528A and 528B are coupled to the voltage-relaxing word line WLK0). The reading transistors 530A and 530B are gated by the reading line WLR0 (e.g., respective gate terminals of the reading transistors 530A and 530B are coupled to the reading line WLR0).

In some implementations, the programming device, the first pair of voltage-relaxing devices, the second pair of voltage-relaxing devices, and the reading devices of the bit cells 320A-320D may include an n-type metal-oxide-semiconductor field-effect-transistor (n-type MOSFET) or sometimes referred to as an NMOS transistor. However, it should be understood that each of the programming/reading devices may include a p-type metal-oxide-semiconductor field-effect-transistor (p-type MOSFET), while remaining within the scope of present disclosure. It should be understood that the programming/reading devices described herein may include or otherwise be any type of transistor or switching device that is suitable for use in a bit cell.

To program the bit cell 520, operations similar to those described in connection with FIG. 1B may be performed, with a programming voltage applied to the programming line WLP0, while turning on the first pair of voltage-relaxing transistors 526A-526B, the second pair of voltage-relaxing transistors 528A-528B, and the reading transistors 530A-530B, while a logic low state is applied to the bit line BL0. This causes the programming transistor 524 to break down and change its electrical behavior to behave as a resistor. Reading processes for the bit cell 520 may be similar to those described in connection with FIG. 1A, and can include concurrently applying a relatively low level of a voltage (sometimes referred to as a reading voltage) on the gate of the programming device 524.

In some implementations, the select voltage applied to WLK0 and WLB0 during a programming operation (e.g., in program mode) can be between the programming voltage applied to WLP0 and the select voltage applied to WLR0. In some implementations, the select voltage applied to WLK0 can be greater than the select voltage applied to WLB0 in program mode. For example, during a programming operation, the select voltage applied to WLK0 may be between about 3V to about 4.5V, and the select voltage applied to WLB0 may be between about 1V to about 3V. However, it should be understood that other voltages may be applied to achieve desired results. During a reading operation, the select voltage applied to WLB0 and WLK0 may be between about 0.5V and 0.9V. If one or more lines are unselected (e.g., the bit cell 520 is not being programmed or read), the unselect voltage applied to the lines may be less than about 0.5V, in some implementations.

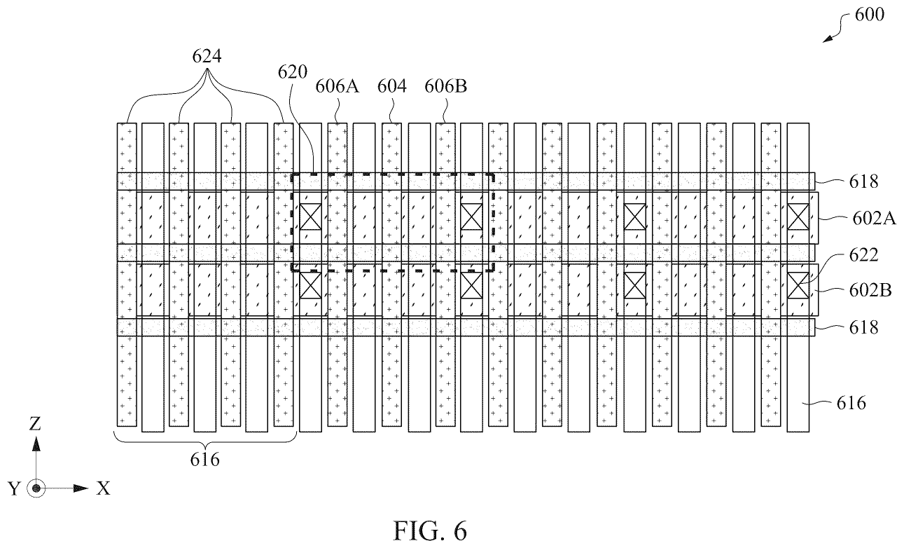

Referring to FIG. 6, illustrated is a block diagram of an example layout 600 for a bit cell 620 of a memory array that includes dummy gate metal layers at an edge of a continuous active region, in accordance with some embodiments. The layout 600 is a top-down layout, in which multiple continuous active regions 602A and 602B are defined. The continuous active regions 602A and 602B may be similar to the continuous active regions 102A and 102B of FIG. 1A, and may include any suitable semiconductor material, for example, silicon, or any other type of semiconductor material described herein. The layout 600 is similar to the layout 100A described in connection with FIG. 1A, but near the edge of the continuous active regions 602A and 602B. The continuous active regions 602A and 602B may sometimes be referred to herein as the OD regions 602A and 602B.

As described in connection with FIGS. 1A, 3A, and 4A, each of the continuous active regions 602A and 602B extend along the X direction as single continuous regions of material, upon which programming devices and reading devices are defined (as described in further detail in connection with FIG. 6). In the example shown in FIG. 6, a bit cell 620 is formed by defining a programming gate structure 604 for a first programming device (e.g., a programming transistor), which may be similar to the first metal gate structure 104 described in connection with FIG. 1A. Additional reading gate structures 606A and 606B are formed to define reading devices (e.g., reading transistors) on either side of the programming device formed using the programming gate structure 604, as shown. The reading gate structures 606A and 606B may be similar to the reading gate structures 106A and 106B described in connection with FIG. 1A.

As shown, the programming gate structure 604 and the reading gate structures 606A and 606B are defined along the direction Y, which is perpendicular to the direction X (e.g., along which the continuous active regions 602A and 602B extend). In this example, the gate structures extend across both the continuous active region 602A and the continuous active region 602B. The gate metal may be separated from the continuous active regions 602A and 602B by a thin layer of a dielectric material, which in some implementations may be a high-k dielectric material. The gate structures described herein may therefore include multiple layers, for example, a gate dielectric layer and a gate metal. Any suitable material may be utilized to form the gate metal of the gate structures described herein, including, for example, PO, or any other metal material described herein.

As described in connection with FIG. 1A, the devices formed using the programming gate structure 604 and the reading gate structures 606A and 606B share source/drain region(s). As shown, the source/drain regions of the programming device and the reading devices may be coupled to a corresponding metal-to-diffusion layer 616. The metal-to-diffusion layers 616 may be similar to the metal-to-diffusion layer 116 of FIG. 1A and may be used to route signals from the source/drain regions of the devices described herein to other circuits. Although not shown here, the programming gate structure 604 and the reading gate structures 606A and 606B, and/or any of the metal-to-diffusion layers 616 may be coupled to various interconnects to couple the bit cell 620 to other logical circuits. Signals used to activate (e.g., program and/or read from) the bit cell 620 are described in connection with FIG. 6.

The continuous active regions 602A and 602B may include one or more conductive vias 622 defined therethrough, which in this example are shown as coupled to the outer source/drain nodes of the reading devices of each bit cell 620. The conductive vias 622, as well as any of the other metal materials described herein, including any gate metals, metal-to-diffusion layers, or interconnect metals, may be formed from, or may otherwise include, aluminum, tungsten, tungsten nitride, copper, cobalt, silver, gold, chrome, ruthenium, platinum, titanium, titanium nitride, tantalum, tantalum nitride, nickel, hafnium, and combinations thereof.

The conductive vias 622 may couple one or more of the source/drain nodes of the pairs of reading transistors with interconnects (e.g., a corresponding bit line), as described herein. As shown, various materials in the layout 600 are shown as separated by the dielectric material 618. For example, a region of the dielectric material 618 electrically isolates the continuous active region 602A from the continuous active region 602B, thereby defining two rows of programming and reading devices as shown in this orientation. The dielectric material may be similar to the dielectric material 114 described in connection with FIG. 1A.

As described herein, the layouts provided in FIGS. 1A, 3A, 4A, 5A, and 6 enable multiple bit cells to be defined along a single continuous active region (e.g., the continuous active region 602A or 602B). To address the LOD effect near the edge of the continuous active regions 602A and 602B, additional dummy gate structures 624 can be defined in a similar pattern to the programming gate structure 604 and the reading gate structures 606A and 606B, as shown. The dummy gate structures 624 create a buffer between the functional bit cells 620 and the edge of the continuous active regions 602A and 602B, ensuring that the uniformity or electrical characteristics of outer devices in the memory array are affected by the LOD effect.

Although three dummy gate structures 624 are shown here, it should be understood that any number of dummy gate structures 624 proximate to the edge of the continuous active regions 602A and 602B may be defined. In one example, the number of dummy gate structures 624 may range from one to ten dummy gate structures 624 defined as shown on the continuous active regions 602A and 602B. The number of dummy gate structures 624 may be selected to optimize both the electrical characteristics of the device and overall device area. The dummy gate structures 624 may be defined using any suitable gate metal described herein, or may be defined using a non-conductive material (e.g., a dielectric). Furhter, although only one edge of the continuous active regions 602A and 602B are shown here (e.g., the left-most edge), it should be understood that similar dummy gate structures 624 may be defined along a second edge of the continuous active regions 602A and 602B (e.g., the right-most edge).

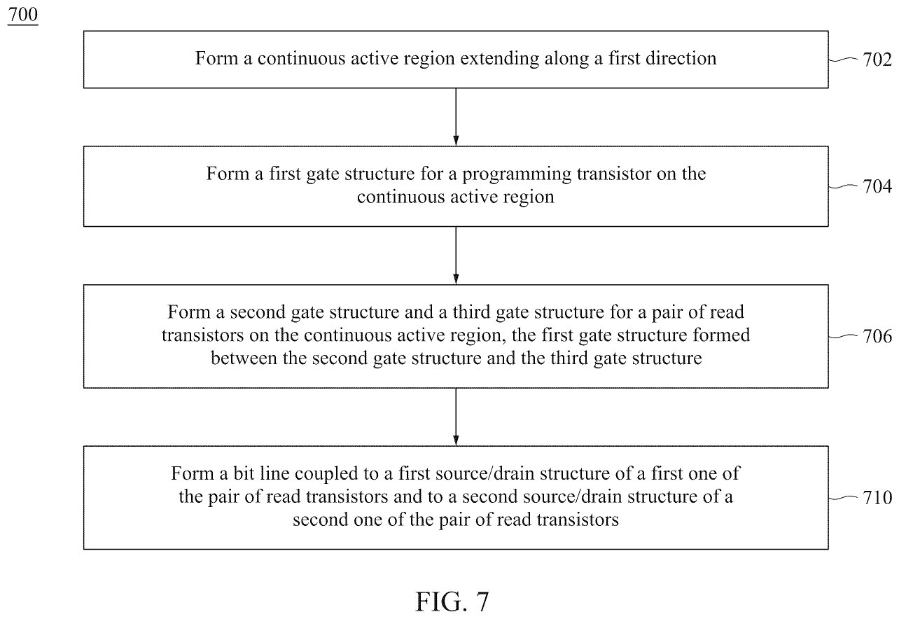

Referring to FIG. 7, illustrated is flow chart of an example method 700 to fabricate the bit cells of FIGS. 1A-6B, in accordance with some embodiments. For example, the method 700 includes operations to fabricate a transistors of an anti-fuse cell upon a continuous active region. It is noted that the method 700 is merely an example and is not intended to limit the present disclosure. Accordingly, it is understood that additional operations may be provided before, during, and after the method 700 of FIG. 7, and that some other operations may only be briefly described herein.

The method 700 starts with operation 702, in which a continuous active region (e.g., the continuous active region 102A and/or the continuous active region 102B of FIG. 1A, etc.) is formed. The continuous active region is formed to expend along a first direction (e.g., the X direction shown in FIG. 1A), upon which programming devices, reading devices, and in some implementations voltage-relaxing devices are to be defined. In some implementations, the continuous active region may be defined upon, or as part of, a substrate material. The substrate may include a semiconductor material substrate, for example, silicon.

In some implementations, the substrate may include other elementary semiconductor material such as, for example, germanium. The substrate may include a compound semiconductor such as silicon carbide, gallium arsenic, indium arsenide, and indium phosphide. The substrate may include an alloy semiconductor such as silicon germanium, silicon germanium carbide, gallium arsenic phosphide, and gallium indium phosphide. In some implementations, the substrate includes an epitaxial layer. For example, the substrate may have an epitaxial layer overlying a bulk semiconductor. Furthermore, the substrate may include an SOI structure. For example, the substrate may include a buried oxide (BOX) layer formed by a process such as separation by implanted oxygen (SIMOX) or other suitable technique, such as wafer bonding and grinding.

In some implementations, defining the continuous active regions as part of or upon the substrate material may include performing shallow trench isolation (STI) to isolate different continuous active regions from each other (e.g., to define the separate continuous active regions 102A and 102B from one another, etc.). The STI process may include etching trenches of predetermined depth into the substrate material, and then filling said trenches with a dielectric material (e.g., the dielectric material 114) to electrically isolate the continuous active regions from one another. In some implementations, multiple parallel continuous active regions that extend along a first direction (e.g., the X direction) may be defined along a second direction (e.g., the Z direction of FIG. 1A) using the STI process. Once the dielectric material has been formed, excess dielectric material may be removed and the top surface of the device can be planarized, for example, using a chemical mechanical polishing (CMP) process.

Source/drain regions may then be formed to defined the source/drain terminals of programming devices (e.g., the programming device 122 of FIG. 1B), reading devices (e.g., the reading devices 124A, 124B of FIG. 1B), and in some implementations voltage-relaxing devices (e.g., one pair of voltage-relaxing devices 326A and 326B of FIG. 3B, multiple pairs of voltage-relaxing devices 426A-426D of FIG. 4B or multiple pairs of voltage-relaxing devices 526A-526B and 528A-528B of FIG. 5B, etc.). In some implementations, the source/drain regions may be formed using a “gate last” or “replacement gate” approach. In such implementations, a dummy gate material (e.g., polysilicon, etc.) can be initially formed and patterned corresponding to the geometry of the gate structures shown in FIGS. 1A, 3A, 4A, 5A, or 6, according to various implementations.

These dummy gate structures can be used as a placeholder during the source/drain region formation. The source/drain regions can be patterned and defined within the continuous active regions. For example, N-type and p-type FETs may be formed by implanting different types of dopants to selected regions of the continuous active regions of the device to form the necessary junction(s). N-type devices can be formed by implanting arsenic (As) or phosphorous (P), and p-type devices can be formed by implanting boron (B). The dummy gate structures may then be removed and replaced by forming active gate structures (e.g., the gate structures for programming devices, reading devices, and in some implementations voltage-relaxing devices, etc.) in steps 704 and 706. In another implementation, e.g., a “first” approach, the method 700 may proceed to steps 704 and 706 to form the metal gate structures prior to forming the source/drain structures.

The method 700 proceeds to operation 704, in which a first gate structure (e.g., the gate structure 104) for a programming transistor (e.g., the programming transistor 122) is formed on the continuous active region. As described herein, the gate structure may include a high-k metal gate structure and may include at least a gate dielectric layer (e.g., a high-k dielectric layer) and a gate metal layer (e.g., a work function metal layer). Forming the gate structures for the programing transistors may including performing any suitable material formation technique, including atomic layer deposition (ALD), chemical vapor deposition (CVD), physical vapor deposition (PVD), plasma-enhanced CVD (PECVD), epitaxial growth or deposition techniques, or combinations thereof. The gate structures may be formed to extend along a second direction that is perpendicular to the first direction. In some implementations, each gate structure formed for a programming device may extend across multiple continuous active regions (e.g., across both the continuous active regions 102A and 102B as shown in FIG. 1A, etc.), thereby defining multiple programming transistors for multiple bit cells that share a single gate structure. The gate structures for the programming devices may be defined using any suitable patterning technique.

The method 700 proceeds to operation 706, in which a second gate structure (e.g., the reading gate structure 106A) and a third gate structure (e.g., the reading gate structure 106B) are formed on the continuous active region. As shown in FIG. 1A, the second and third gate structures may be formed such that the first gate structure is formed between the second and third gate structures. In some implementations, the first, second, and third gate structures may be defined concurrently using the same material deposition process. In some implementations, one or more voltage-relaxing gate structures (e.g., the voltage-relaxing gate structures 306A and 306B, the voltage-relaxing gate structures 406A-406D, the first voltage-relaxing gate structures 506A-506B and the second voltage-relaxing gate structures 508A-508B, etc.).

Forming the gate structures for the programing transistors may including performing any suitable material formation technique, including ALD, CVD, PVD, PECVD, epitaxial growth or deposition techniques, or combinations thereof. The gate structures may be formed to extend along a second direction that is perpendicular to the first direction. In some implementations, each gate structure formed for the reading transistors and/or voltage-relaxing devices may extend across multiple continuous active regions, thereby defining multiple reading transistors and/or voltage-relaxing devices for multiple bit cells that share a single gate structure. The gate structures for the reading devices and/or voltage-relaxing devices may be defined using any suitable patterning technique.

In implementations in which the voltage-relaxing devices are formed, the gate structures for the voltage-relaxing gate structures may be formed such that voltage-relaxing devices are defined between the programming device(s) and the reading device(s), as shown in FIGS. 3A, 4A, and 5A. In some implementations, the programming devices, voltage-relaxing devices, and reading devices may be defined in a symmetrical configuration. In some implementations, rather than defining two of each of the programming devices, pairs of voltage-relaxing devices, and pairs of reading devices, as described in connection with FIGS. 4A and 4B, any positive integer number of programming devices, pairs of voltage-relaxing devices, and pairs of reading devices may be formed. Likewise, any integer multiple of the devices described in connection with FIGS. 5A and 5B, may be formed in series with one another to achieve useful results.

In some implementations, in addition to forming high-k metal gate structures for the devices described herein, dummy gate structures may be formed near the ends of the continuous active regions, as described in connection with FIG. 6. The dummy gate structures may include similar high-k/metal materials to those described herein, or other materials such as polysilicon or dielectric materials. The dummy gate structures can define non-functional regions continuous active regions, such that the functional bit cells formed according to the techniques described herein may not be affected by the LOD effect. The dummy gate structures may be formed in the same pattern as the gate structures for the programming devices, reading devices, and voltage-relaxing devices described herein, as shown in FIG. 6. The dummy gate structures may be formed concurrently with the gate structures for the programming devices, reading devices, and voltage-relaxing devices, or may be formed in a separate step using a suitable material deposition technique. The number of dummy gate structures may be one to ten dummy gate structures, in some implementations.

The method 700 proceeds to operation 710, in which one or more bit lines (e.g., the BL0, BL1, one or more of the metal layers 218, 220, 222, 232, or 236 of FIGS. 2A-2B, etc.) are formed. The bit lines can be coupled to a first source/drain structure of a first one of the pair of reading transistors and to a second source/drain structure of a second one of the pair of reading transistors. The bit lines may be formed, in some implementations, using one or more of a front-side metallization process or a back-side metallization process. For example, various interconnect structures, including conductive vias, metal-to-diffusion layers, or other types of metal layers may be formed on the continuous active regions and/or the gate structures formed in previous steps of the method 700 to form the bit lines and other structures to couple the bit cells described herein to other circuits.

Any suitable number of interconnect structures may be formed to achieve useful results and to couple the various components of the bit cells to one another. For example, conductive vias may be formed to connect the gate terminals of one or more programming transistors to a programming word line, and additional conductive vias may be formed to connect gate terminals of the reading transistors to a common reading word line, and to connect gate terminals of voltage-relaxing devices to corresponding voltage-relaxing lines, according to the configurations described herein. Metal-to-diffusion layers and corresponding vias may be formed to connect source terminals of the reading transistors, as described herein, to one or more bit lines.

The bit lines, as well as other layers that correspond to programming lines, read select lines, or voltage-relaxing select lines, may be formed from metal material layers. The metal material can be selected from the group consisting of aluminum, tungsten, tungsten nitride, copper, cobalt, silver, gold, chrome, ruthenium, platinum, titanium, titanium nitride, tantalum, tantalum nitride, nickel, hafnium, and combinations thereof. Other metal materials are within the scope of the present disclosure. The interconnect structures can be formed by overlaying the workpiece with the above-listed metal material by, for example, CVD, PVD, electroless plating, electroplating, or combinations thereof.

In one aspect of the present disclosure, a memory array is disclosed. The memory array includes: a continuous active region extending along a direction; a first memory cell comprising a first programming device and a pair of first reading devices defined on the continuous active region; a first programing word line coupled to a gate of the first programing device; a first reading word line coupled to gates of the pair of first reading devices; and a bit line. In the memory array, a first one of the pair of first reading devices is coupled between a first source/drain node of the first programing device and the bit line.

In another aspect of the present disclosure, a circuit is disclosed. The circuit includes: a first programming transistor defined on a continuous active region; and a pair of reading transistors defined on the continuous active region along a direction, the first programming transistor positioned between the pair of reading transistors, wherein respective first source/drain nodes of the pair of reading transistors are each coupled to a bit line.

In yet another aspect of the present disclosure, a method for fabricating a memory device is disclosed. The method includes forming a continuous active region extending along a first direction; forming a first gate structure for a programming transistor on the continuous active region; forming a second gate structure and a third gate structure for a pair of reading transistors on the continuous active region, the first gate structure formed between the second gate structure and the third gate structure; and forming a bit line coupled to a first source/drain structure of a first one of the pair of reading transistors and to a second source/drain structure of a second one of the pair of reading transistors.

As used herein, the terms “about” and “approximately” generally mean plus or minus 10% of the stated value. For example, about 0.5 would include 0.45 and 0.55, about 10 would include 9 to 11, about 1000 would include 900 to 1100.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A memory array, comprising:
a bit line;
a programming device coupled to a programming word line; and
a reading device coupled to a reading word line and coupled between the programming device and the bit line.

2. The memory array of claim 1, wherein the reading device is in series with the programming device.

3. The memory array of claim 1, wherein the reading device comprises an n-type transistor.

4. The memory array of claim 1, further comprising an isolation structure surrounding a continuous active region upon which the programming device and the reading device are defined.

5. The memory array of claim 1, wherein the reading device is a first reading device, and further comprising a second reading device coupled between the programming device and the bit line.

6. The memory array of claim 5, wherein the first reading device, the programming device, and the second reading device are in series.

7. The memory array of claim 1, further comprising a voltage-relaxing device coupled between the programming device and the reading device.

8. The memory array of claim 7, further comprising a voltage-relaxing line coupled to the voltage-relaxing device.

9. The memory array of claim 7, wherein the voltage-relaxing device is in series with the programming device and the reading device.

10. The memory array of claim 1, further comprising a conductive via connecting the reading device to the bit line.

11. The memory array of claim 1, further comprising a dummy gate structure.

12. A memory circuit, comprising:
a programming transistor coupled between a pair of voltage-relaxing transistors; and
a reading transistor coupled to a reading word line and coupled to a first voltage-relaxing transistor of the pair of voltage-relaxing transistors.

13. The memory circuit of claim 12, wherein the reading transistor is in series with the first voltage-relaxing transistor and the programming transistor.

14. The memory circuit of claim 12, wherein a gate of the programming transistor comprises a first gate dielectric layer configured to be broken down to represent a first logic state.

15. The memory circuit of claim 12, wherein a gate of the reading transistor is coupled to a reading word line.

16. The memory circuit of claim 12, wherein a gate of the reading transistor and a gate of the programming transistor are parallel to one another.

17. The memory circuit of claim 12, further comprising a conductive via coupling the reading transistor to a bit line.

18. A method for fabricating a memory device, comprising:
forming a first gate structure for a programming transistor; and
forming a second gate structure and a third gate structure for a pair of reading transistors, wherein the second gate structure and the third gate structure are formed such that the first gate structure is between the second gate structure and the third gate structure.

19. The method of claim 18, further comprising forming a bit line coupled to the pair of reading transistors.

20. The method of claim 18, further comprising forming a metal layer for a programming line coupled to the first gate structure of the programming transistor.
